(19) United States
(12) Patent Application Publication
(10) Pub. No.: US 2013/0320304 A1
(43) Pub. Date: Dec. 5, 2013

(54) Carrier transport material and electronic device

(71) Applicants: Yi-Ming Chang, Hsinchu City (TW); Rui Zhu, Jiangsu (CN)

(72) Inventors: Yi-Ming Chang, Hsinchu City (TW); Rui Zhu, Jiangsu (CN)

(73) Assignee: INDUSTRIAL TECHNOLOGY RESEARCH INSTITUTE, Hsinchu (TW)

(21) Appl. No.: 13/481,972

(22) Filed: May 29, 2012

(51) Int. Cl. H01G 9/028; H01L 51/46; H01L 51/54; H01L 51/30

(52) U.S. Cl. 257/40; 252/62.2; 257/E51.012; 257/E51.005; 257/E51.018

(57) ABSTRACT

A carrier transport material and an electronic device are provided. The carrier transport material includes a conjugated polyelectrolyte and a functional organic molecule. The conjugated polyelectrolyte includes a conjugated backbone and at least one alkyl side-chain, where a tail end of the alkyl side-chain has a first ionic group. The functional organic molecule includes a functional main-chain and a second ionic group located at a tail end of the functional organic molecule. Electrostatic attraction is formed between the first ionic group of the conjugated polyelectrolyte and the second ionic group of the functional organic molecule, and the carrier transport material presents an electrically neutral state.

### TECHNICAL FIELD

The disclosure relates to a carrier transport material and an electronic device.

### BACKGROUND

According to current techniques, in order to achieve high efficiency, a calcium (Ca) electrode with low work function, and an aluminium (Al) layer formed on a surface of the Ca electrode to both serve as an electrode and a passivation layer are used in most of electronic devices. However, the Ca electrode should be formed with vacuum evaporation, and activity of calcium may lead to a poor lifespan of the device. Therefore, an interlayer is added between the electrode and an active layer to modify an interface property to ameliorate carrier transport efficiency between the electrode and the active layer.

In recent years, since an electrolyte having ion characteristics has a dipole characteristic, which avails inducing electrons to move towards a single direction on a semiconductor interface to improve electron transport capability, it is one of candidate materials of the novel interlayer. A small molecule electrolyte generally forms a film through self-assembly, which has unsatisfactory evenness and coverage rate. Since a polymer material such as poly(ethylene oxide) (PEO) or poly(sytrene sulfonate) (PSS) is a water-soluble material, the problem of mutual dissolution with the active layer after filming is avoided. Meanwhile, the polymer material has a better film forming property, which avails applying a coating process, and is complied with a processing design concept of an organic device. However, since PEO and PSS are all non-conductive, such type of material is required to have an extremely thin film thickness (several nanometers) in order to implement interface modification without causing a large resistance.

### SUMMARY

The disclosure provides a carrier transport material including a conjugated polyelectrolyte and a functional organic molecule. The conjugated polyelectrolyte includes a conjugated backbone and at least one alkyl side-chain, where an end of the alkyl side-chain has a first ionic group. The functional organic molecule includes a functional main-chain and a second ionic group located at an end of the functional organic molecule. An Electrostatic attraction is formed between the first ionic group of the conjugated polyelectrolyte and the second ionic group of the functional organic molecule, and the carrier transport material presents an electrical neutral state.

The disclosure provides an electronic device including a first electrode, a second electrode, an active layer and a first electron transport layer. The first electrode and the second electrode are disposed opposite to each other. The active layer is disposed between the first electrode and the second electrode. The first electron transport layer is disposed between the active layer and the first electrode, where the first electron transport layer includes the aforementioned carrier transport material.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a cross-sectional view of an electronic device according to an embodiment of the disclosure.

FIG. 1B is a cross-sectional view of an electronic device according to another embodiment of the disclosure.

FIG. 2 is a reaction schematic diagram of electrostatic attraction between a cationic group of PTMAHT and an anionic group of DBSA.

FIG. 3 is a proton nuclear magnetic resonance spectrum (¹H-NMR) of PTMAHT:DBSA.

FIG. 4 is a visible absorption spectrum of a liquid state and a solid state of PTMAHT:DBSA and PTMAHT.

FIG. 5 is a current density and voltage (I-V) diagram of solar cells of an embodiment 1 and examples 1-3.

FIG. 6 illustrates a relationship between time and open-circuit voltages (V_{oc}) of solar cells of an embodiment 1 and examples 2 and 4.

FIG. 7 illustrates a relationship between time and short-circuit current densities (J_{sc}) of solar cells of an embodiment 1 and examples 2 and 4.

FIG. 8 illustrates a relationship between time and fill factors (FF) of solar cells of an embodiment 1 and examples 2 and 4.

FIG. 9 illustrates a relationship between time and photoelectric conversion efficiencies (PCEs) of solar cells of an embodiment 1 and examples 2 and 4.

FIG. 10 is a current density and voltage (I-V) diagram of solar cells of an embodiment 2 and examples 5 and 6.

FIG. 11 is a current density and voltage (I-V) diagram of solar cells of an embodiment 3 and an example 2.

FIG. 12 is a current density and voltage (I-V) diagram of solar cells of an embodiment 7 and an example 10.

### DETAILED DESCRIPTION OF DISCLOSED EMBODIMENTS

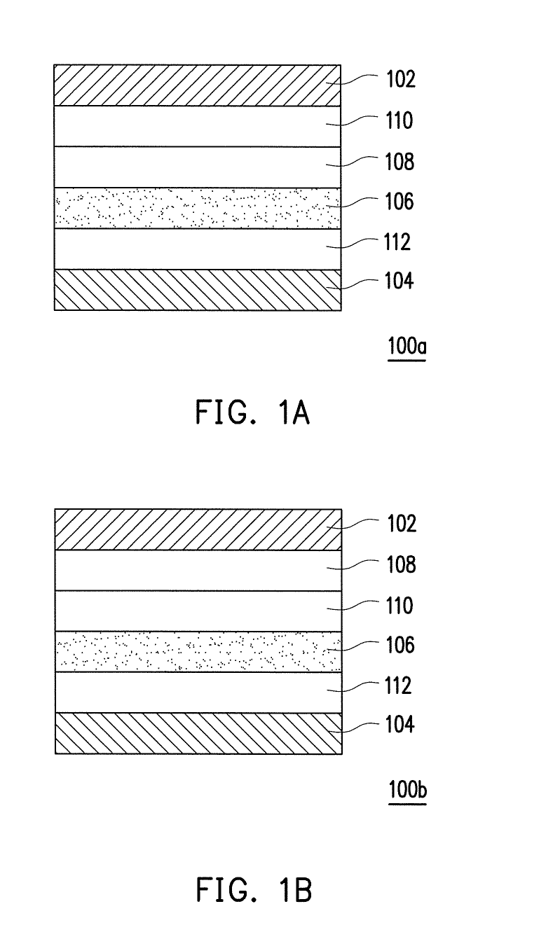

FIG. 1A is a cross-sectional view of an electronic device according to an embodiment of the disclosure. Referring to FIG. 1A, the electronic device 100a includes a first electrode 102, a second electrode 104, an active layer 106 and a first electron transport layer 108. The first electrode 102 and the second electrode 104 are disposed opposite to each other. The active layer 106 is located between the first electrode 102 and the second electrode 104. The first electron transport layer 108 is located between the active layer 106 and the first electrode 102.

The first electrode 102 and the second electrode 104 are, fore example, respectively a metal material, a transparent conductive material or other suitable conductive material.

The active layer 106 is, for example, an active layer of a thin-film transistor, an active layer of a solar cell or a light-emitting material layer of an organic light-emitting diode. In detail, when the electronic device 100a is a thin-film transistor, the active layer 106 is, for example, the active layer of the thin-film transistor. When the electronic device 100a is a solar cell, the active layer 106 is, for example, the active layer of the solar cell. When the electronic device 100a is an organic light-emitting diode, the active layer 106 is, for example, a light-emitting material layer. However, the disclosure is not limited thereto.

In the present embodiment, the first electron transport layer 108 is an interlayer between the active layer 106 and the first electrode 102. The first electron transport layer 108 includes a carrier transport material, so that it has effects of interface modification and prompting electron transport.

Moreover, the electronic device 100a of the disclosure may further include a second electron transport layer 110. The first electron transport layer 108 is located between the active layer 106 and the first electrode 102, and the second electron transport layer 110 is located between the first electron transport layer 108 and the first electrode 102. A material of the second electron transport layer 110 includes an inorganic oxide, and the inorganic oxide includes zinc oxide (ZnO), titanium oxide (TiOx) or indium tin oxide (ITO). However, positions of the first electron transport layer 108 and the second electron transport layer 110 between the active layer 106 and the first electrode 102 are not limited by the disclosure. In other embodiments, the second electron transport layer 110 of an electronic device 100b can also be located between the active layer 106 and the first electron transport layer 108, as that shown in FIG. 1B.

Referring to FIG. 1A, in order to further improve a hole transport efficiency, the electronic device 100a may also include a hole transport layer 112. The hole transport layer 112 is located between the active layer 106 and the second electrode 104, which avails improving the hole transport efficiency between the active layer 106 and the second electrode 104.

The carrier transport material is further described below.

The carrier transport material includes a conjugated polyelectrolyte and a functional organic molecule, where electrostatic attraction is formed between the conjugated polyelectrolyte and the functional organic molecule, and the carrier transport material presents an electrical neutral state.

In the present embodiment, the conjugated polyelectrolyte includes a conjugated backbone and at least one alkyl side-chain, where an end of the alkyl side-chain has a first ionic group. The functional organic molecule includes a functional main-chain and a second ionic group located at an end of the functional organic molecule. The electrostatic attraction is formed between the first ionic group of the conjugated polyelectrolyte and the second ionic group of the functional organic molecule to form a stable complex, and the carrier transport material presents an electrical neutral state. It is noticed that none chemical bonding is formed between the conjugated polyelectrolyte and the functional organic molecule, so that the effects of the conjugated polyelectrolyte and the functional organic molecule can simultaneously function.

In detail, the conjugated polyelectrolyte has a conjugated structure and an ionic group, which may produce an intense dipole function between the first electrode 102 and the active layer 106 to reduce a potential obstacle and induce carriers to inject into the active layer, so as to reduce a driving voltage. In other words, the conjugated polyelectrolyte may increase carrier transport efficiency of the carrier transport material.

Regarding the conjugated polyelectrolyte, the backbone having the conjugated structure is, for example, benzene, thiophene, aniline, furan, phenyl vinylene, fluorine or a copolymer of any combination of the above compound. Moreover, the first ionic group is, for example, a cationic group containing nitrogen.

Moreover, since the conjugated polyelectrolyte is generally a water-soluble material, when the carrier transport material having the conjugated polyelectrolyte is to be coated on a hydrophobic surface of a substrate or a film layer, a carrier transport material solution on the hydrophobic surface probably has poor wettability, which may produce a non-continuous film layer. It is noticed that in the present embodiment, the functional organic molecules are added to the carrier transport material to enhance a coating characteristic thereof.

For example, the functional main-chain of the functional organic molecule is, for example, a hydrophobic or cross-linking compound, so that when the carrier transport material is coated on the surface of the substrate or the film layer, it may have a good coating characteristic to form a continuous film layer. Moreover, after the carrier transport material containing the functional organic molecules is coated on the surface of the substrate or a member, it may further change a surface characteristic of the substrate or the member. The surface characteristic is, for example, a water contact angle.

In the present embodiment, the functional main-chain of the functional organic molecule is, for example, aromatics with an alkyl chain, aromatics with fluorine-contained groups, aromatics with cross-linkable groups, aliphatics with an alkyl chain, aliphatics with fluorine-contained groups, or aliphatics with cross-linkable groups. Moreover, the second ionic group is, for example, an anionic group.

Moreover, since the conjugated polyelectrolyte has the first ionic group, and the ionic group generally has good hydrophilicity, moisture in the air is easy to be absorbed by the ionic groups, which may cause poor stability of the electronic device 100a. In the present embodiment, the functional organic molecules are added to mitigate the above problem.

For example, an electrostatic attraction phenomenon is formed between the second ionic group in the functional organic molecule of the carrier transport material and the first ionic group of the conjugated polyelectrolyte, so that the moisture in the air is not liable to be absorbed on the carrier transport material, and the electronic device 100a is not easy to be influenced by the moisture and has good stability, by which reliability of the electronic device 100a is improved.

In detail, the conjugated polyelectrolyte of the present embodiment, for example, has a structure shown as a formula 1, a formula 2 or a formula 3:

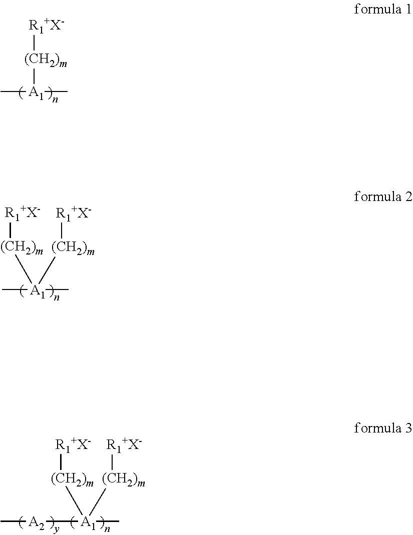

Where, A₁ is a main-chain having conjugated double bonds or conjugated triple bonds, A₂ is a main-chain having conjugated double bonds or conjugated triple bonds, R₁⁺ is a cationic group, X⁻ is an anion, in is 3˜18, n is 2˜1000, and y is 2˜1000.

Moreover, the functional organic molecule of the present embodiment, for example, has a structure shown as a formula 4:

A₃-R₂⁻M⁺ formula 4

Where, A₂ is an aromatic main-chain or an aliphatic main-chain, R₂⁻ is an anionic group, and M⁺ is a cation.

In the present embodiment, R₁⁺ in the conjugated polyelectrolyte is, for example, N⁺(CH₃)₃, N⁺(C₂H₅)(CH₃)₂, N⁺(C₂H₅)₂CH₃ or

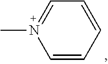

X⁻ is F⁻, Cl⁻, Br⁻ or I⁻, and M⁺ is Li⁺, Na⁺, K⁺ or Rb⁺. Moreover, R₂⁻ in the functional organic molecule is, for example, SO₃⁻.

Further, the conjugated polyelectrolyte of the present embodiment, for example, includes at least one of following:

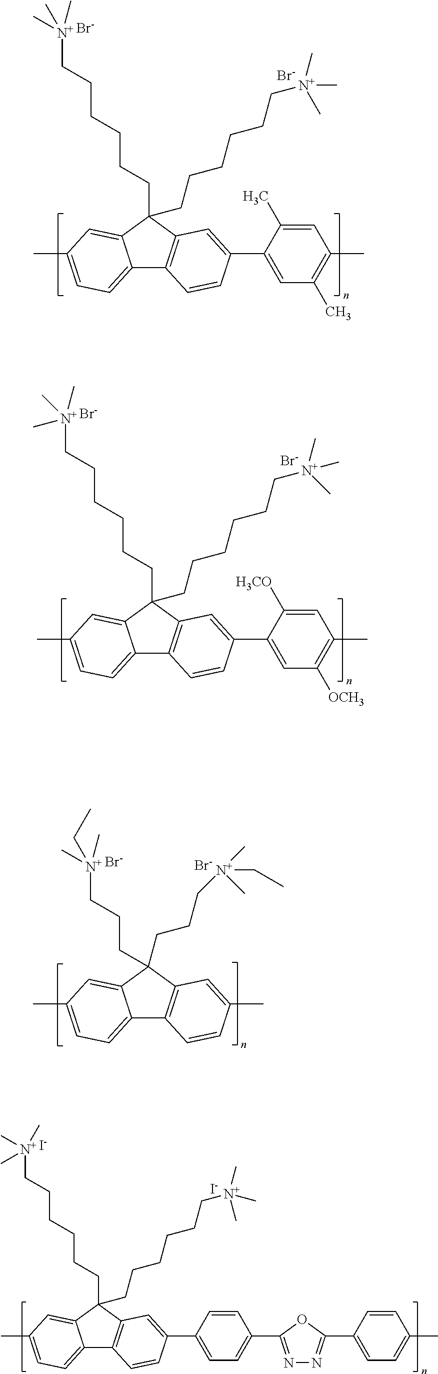

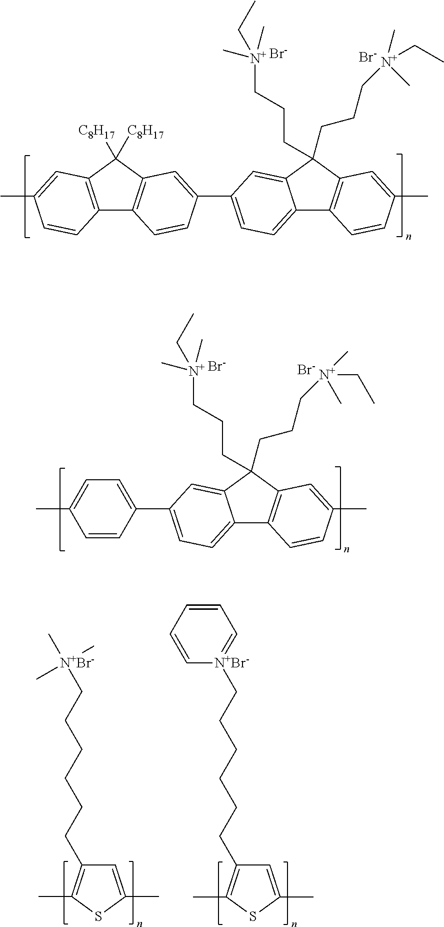

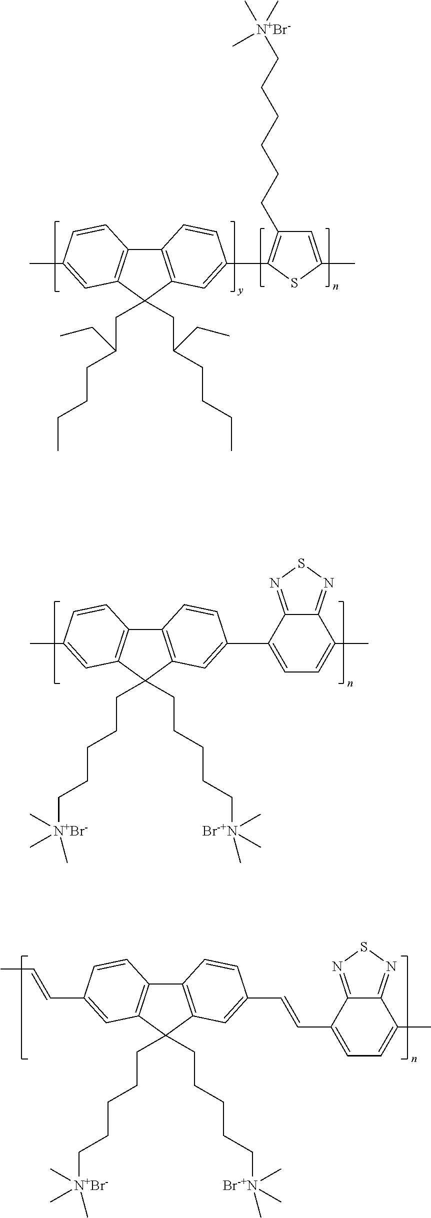

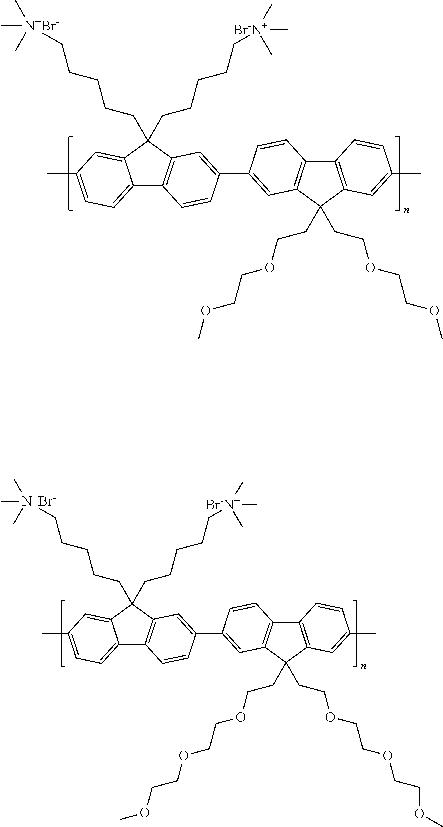

Where, n is 2˜1000 and y is 2˜1000.

Moreover, the functional organic molecule of the present embodiment, for example, includes at least one of following:

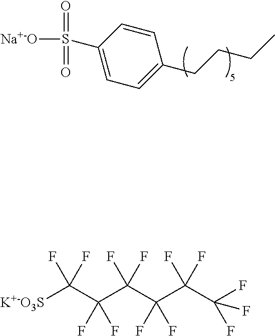

Embodiments are provided below to apply the carrier transport material to the solar cell, and a plurality of experiments are performed to verify the effect of the disclosure.

### Embodiment 1

The first electrode is Al, the conjugated polyelectrolyte of the carrier transport material used by the first electron transport layer is PTMAHT, the functional organic molecule is DBSA, the active layer is poly-(3-hexylthiophene) (P3HT) blend with phenyl-C61-butyric acid methyl ester (PCBM), the hole transport layer is poly(3,4-ethylenedioxy thiophene): polystyrenesulfonate (PEDOT:PSS), and the second electrode is ITO. Structures of PTMAHT and DBSA are shown in a following table one.

TABLE1

| PTMAHT | DBSA |
|---|---|
| 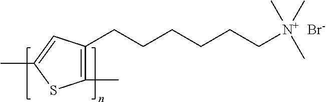 | 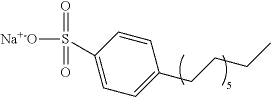 |

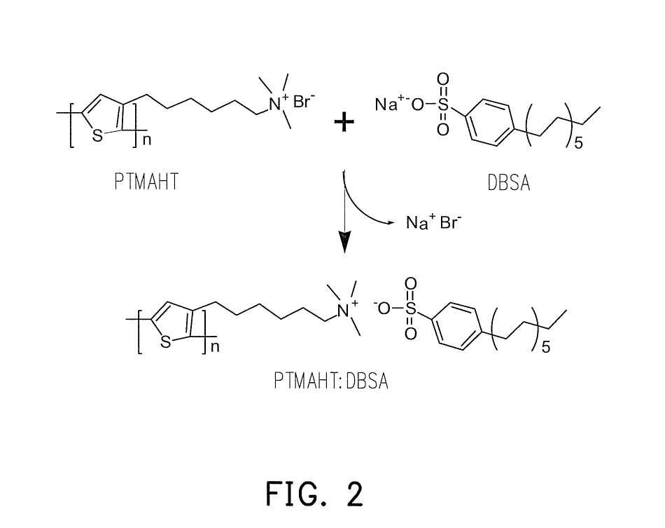

After the PTMAHT and the DBSA are respectively dissolved in water and are merged, the cationic group N⁺(CH₃)₃ of the PTMAHT and the anionic group SO₃⁻ of the DBSA may have an ionic sorption effect to form a complex PTMAHT:DBSA, and a reaction schematic diagram is as that shown in FIG. 2. The complex PTMAHT:DBSA is not dissolved in water, and after the complex PTMAHT:DBSA is collected and purified, it is dissolved in methanol to form the carrier transport material.

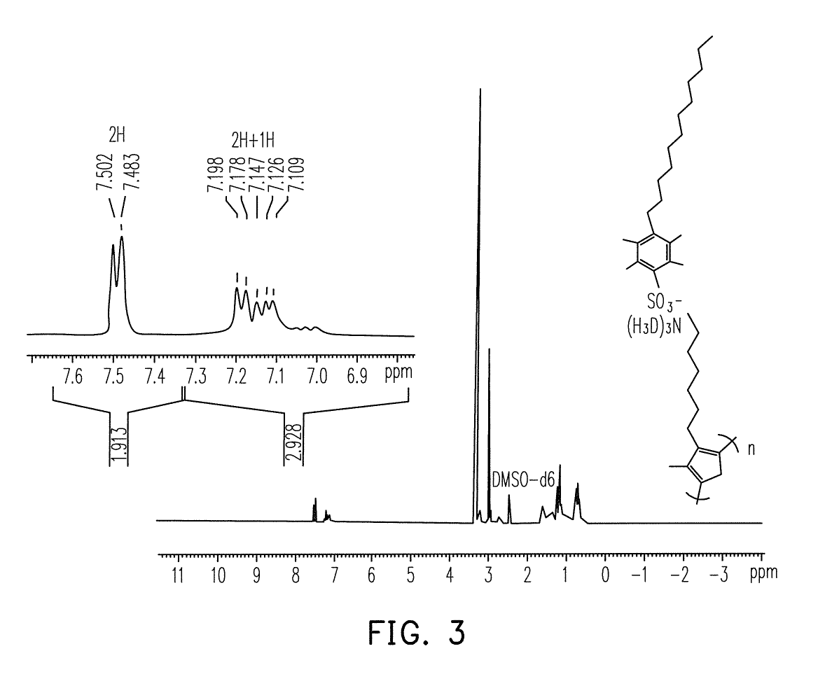

FIG. 3 is a proton nuclear magnetic resonance spectrum (¹H-NMR) of the complex PTMAHT:DBSA, and a used solvent is DMSO-d6. According to chemical shifts of hydrogen atoms on aromatic rings of the PTMAHT and the DBSA, it is determined that the PTMAHT and the DBSA indeed exist to form the complex PTMAHT:DBSA.

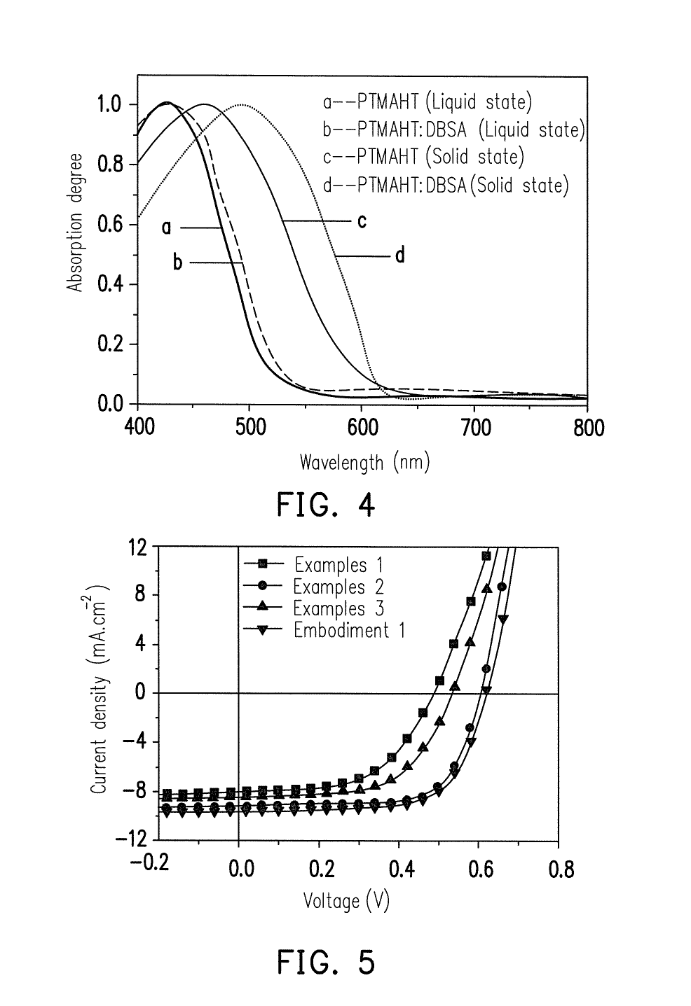

FIG. 4 is a visible absorption spectrum of a liquid state and a solid state of the PTMAHT:DBSA and the PTMAHT. A difference between the PTMAHT and the PTMAHT:DBSA is determined according to a relative position thereof.

### Example 1

In the example 1 (serving as a comparative example), the first electrode is an Al electrode, and the first electron transport layer is not configured. Materials of the active layer, the hole transport layer and the second electrode are all the same to that of the embodiment 1.

### Example 2

In the example 2 (serving as a comparative example), the first electrode is a Ca/Al electrode, and the first electron transport layer is not configured. Materials of the active layer, the hole transport layer and the second electrode are all the same to that of the embodiment 1.

### Example 3

In the example 3 (serving as a comparative example), the first electrode is the Al electrode. The first electron transport layer is the DBSA, and the materials of the active layer, the hole transport layer and the second electrode are all the same to that of the embodiment 1.

Measurement 1: comparison of device performance

FIG. 5 is a current density and voltage (I-V) diagram of the solar cells of the embodiment 1 and the examples 1-3. A table two records data measured in the embodiment 1 and the examples 1-3 and power conversion efficiencies (PCE) of the solar cells. According to the following table two, it is known that the PCE of the solar cell of the embodiment 1 may reach 4.01% maximum and a fill factor (FF) value may reach 67.8%, which is not only better than that of the examples 1-3, but also a fabrication process of the carrier transport material is simple, and complicated chemical synthesis steps are not required.

TABLE 2

| | V_{oc}(V) | J_{sc}(mA/cm⁻²) | FF(%) | PCE(%) |
|---|---|---|---|---|
| Example 1 | 0.48 | 7.97 | 55.3 | 2.12 |
| Example 2 | 0.60 | 9.14 | 69.4 | 3.81 |
| Example 3 | 0.53 | 8.45 | 58.8 | 2.63 |
| Embodiment 1 | 0.62 | 9.54 | 67.8 | 4.01 |

### Example 4

In the example 4 (serving as a comparative example), the first electrode is the Al electrode. The first electron transport layer is the PTMAHT, and the materials of the active layer, the hole transport layer and the second electrode are all the same to that of the embodiment 1.

### Measurement 2: Device Stability Analysis

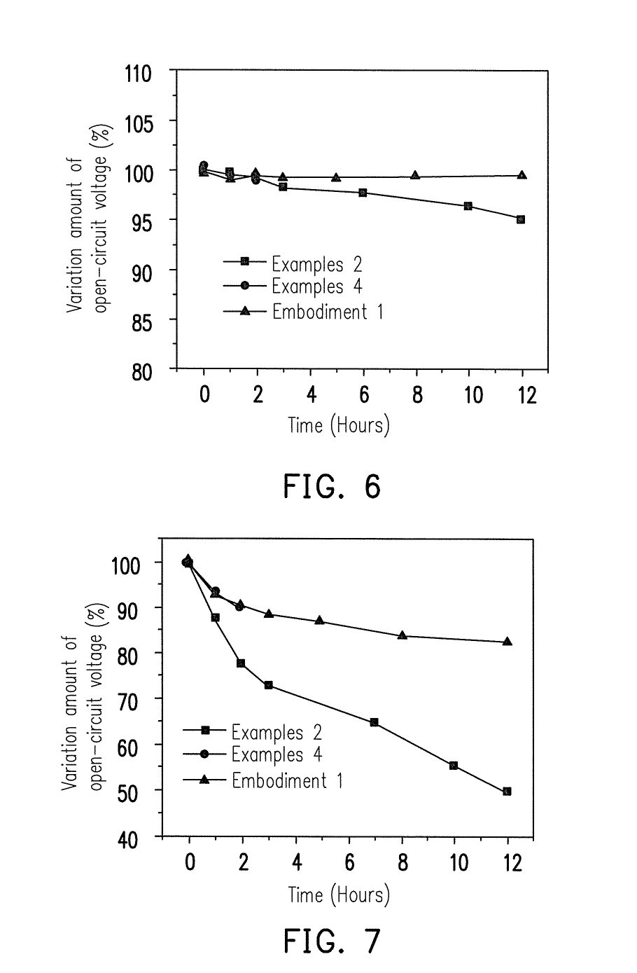

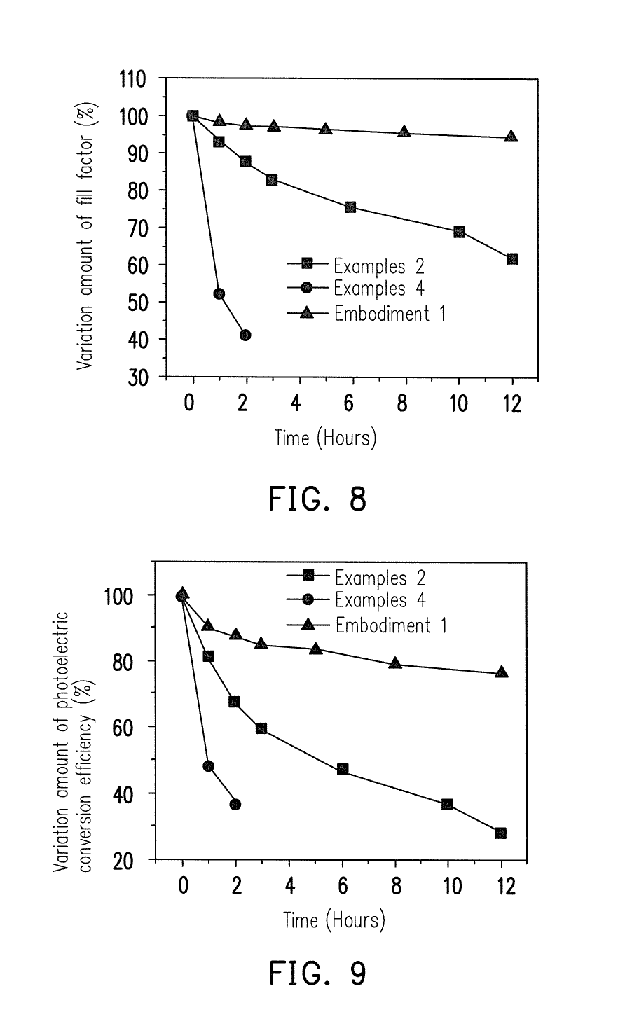

FIG. 6 illustrates a relationship between time and degraded rates of open-circuit voltages (V_{OC}) of the solar cells of the embodiment 1 and the examples 2 and 4. FIG. 7 illustrates a relationship between time and degraded rates of short-circuit current densities (J_{sc}) of the solar cells of the embodiment 1 and the examples 2 and 4. FIG. 8 illustrates a relationship between time and degraded rates of fill factors (FF) of the solar cells of the embodiment 1 and the examples 2 and 4. FIG. 9 illustrates a relationship between time and degraded rates of PCEs of the solar cells of the embodiment 1 and the examples 2 and 4.

According to FIG. 6 and FIG. 8, it is known that the solar cell of the embodiment 1 still maintains good stability while it is exposed in the air. According to FIG. 9, after the solar cell of the embodiment 1 is exposed in the air for 12 hours, the solar cell still has a PCE of 80%.

### Embodiment 2

The first electrode is Al, the conjugated polyelectrolyte of the carrier transport material is PTMAHT, the functional organic molecule is DBSA, the active layer is PTB7 plus PC₇₁BM, the hole transport layer is PEDOT:PSS, and the second electrode is ITO. Structures of PTB7 and PC₇₁BM are shown in a following table three.

TABLE 3

| PTB7 | PC₇₁BM |
|---|---|
| 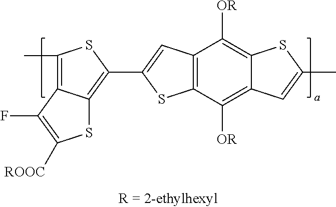 | 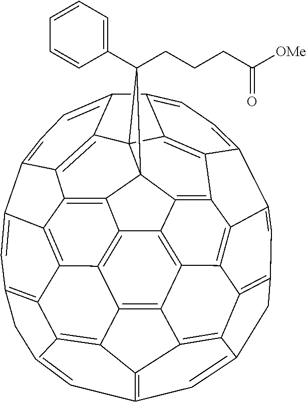 |

### Example 5

In the example 5 (serving as a comparative example), the first electrode is an Al electrode, and the first electron transport layer is not configured. Materials of the active layer, the hole transport layer and the second electrode are all the same to that of the embodiment 2.

### Example 6

In the example 6 (serving as a comparative example), the first electrode is a Ca/Al electrode, and the first electron transport layer is not configured. Materials of the active layer, the hole transport layer and the second electrode are all the same to that of the embodiment 2.

### Measurement 3: Comparison of Device Performance

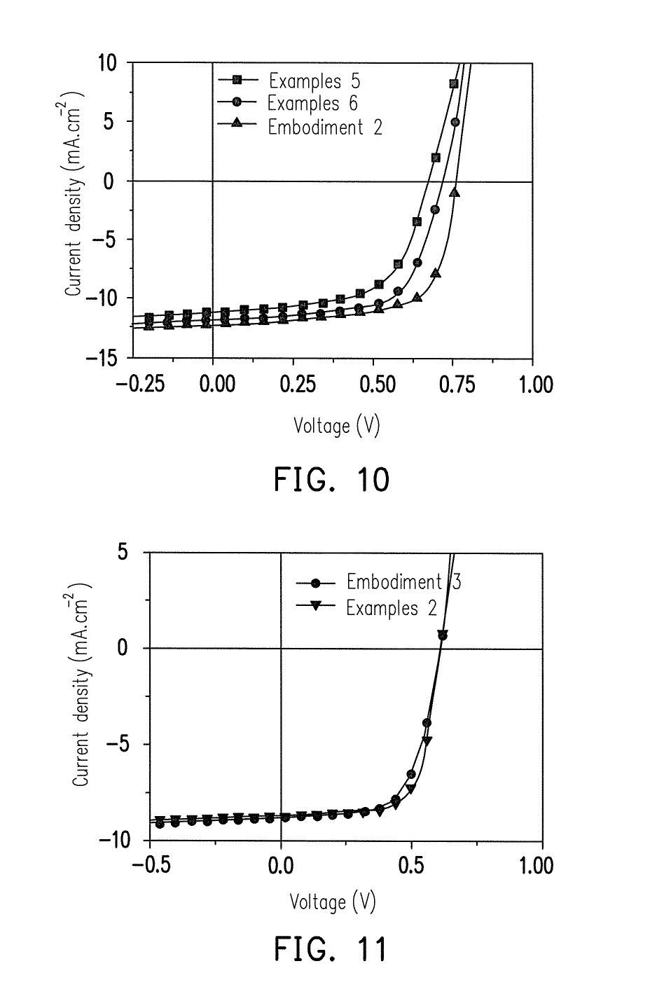

FIG. 10 is a current density and voltage (I-V) diagram of the solar cells of the embodiment 2 and the examples 5 and 6. A table four records data measured in the embodiment 2 and the examples 5 and 6 and PCEs of the solar cells. According to the following table four, it is known that the PCE of the solar cell of the embodiment 2 may reach 6.47% maximum and an FF value may reach 68.3%, which is better than that of the examples 5 and 6, and compared to the example 6, the PCE of the solar cell of the embodiment 2 is 19% higher than that of the example 6.

TABLE 4

| | V_{oc}(V) | J_{sc}(mA/cm⁻²) | FF(%) | PCE(%) |
|---|---|---|---|---|
| Example 5 | 0.68 | 11.2 | 60.0 | 4.57 |
| Example 6 | 0.72 | 11.9 | 63.7 | 5.46 |
| Embodiment 2 | 0.77 | 12.3 | 68.3 | 6.47 |

### Embodiment 3

The first electrode is Al, the conjugated polyelectrolyte of the carrier transport material is PTMAHT, the active layer is P3HT plus PCBM, the hole transport layer is PEDOT:PSS, and the second electrode is ITO. A structure of the functional organic molecule is shown as follows.

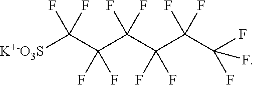

### Measurement 4: Comparison of Device Performance

FIG. 11 is a current density and voltage (I-V) diagram of the solar cells of the embodiment 3 and the example 2.

A plurality of embodiments are provided below to describe a surface modification effect of the carrier transport material of the disclosure.

### Measurement 5

In the example 7 (serving as a comparative example), a contact angle of water on the surface of the active layer of the embodiment 1 is measured. In the embodiment 4, a contact angle of water on the surface of the first electron transport layer of the embodiment 1 is measured.

TABLE 5

| | Contact angle |
|---|---|
| Example 7 | 105° |
| Embodiment 4 | 70.6° |

### Measurement 6

In the example 8 (serving as a comparative example), a contact angle of water on the surface of a glass substrate is measured. In the embodiment 5, the first electron transport layer of the embodiment 3 is coated on the glass substrate and a contact angle of water on the surface of the first electron transport layer is measured, and a result is shown in a following table 6.

TABLE 6

| | Contact angle of |
|---|---|
| | water |
| Example 8 | 4.9° |
| Embodiment 5 | 79.2° |

### Measurement 7

In the example 9 (serving as a comparative example), a contact angle of water on the surface of the active layer of the embodiment 3 is measured. In the embodiment 6, the first electron transport layer of the embodiment 3 is coated on the active layer of the embodiment 3 and a contact angle of water on the surface of the first electron transport layer is measured, and a result is shown in a following table 7.

TABLE 7

| | Contact angle of |
|---|---|
| | water |
| Example 9 | 112° |
| Embodiment 6 | 89.8° |

According to the measurements 5-7, it is known that by coating the first electron transport layer of the disclosure on the surface of the substrate or film layer, the effect of surface modification is indeed achieved.

### Embodiment 7

The first electrode is Al, the conjugated polyelectrolyte of the carrier transport material is PTMAHT, the functional organic molecule is DBSA, the active layer is PTPTBT plus PC₇₁BM, the hole transport layer is PEDOT:PSS, and the second electrode is ITO. A structure of the PTPTBT is shown in a following table 8.

TABLE 8
PTPTBT

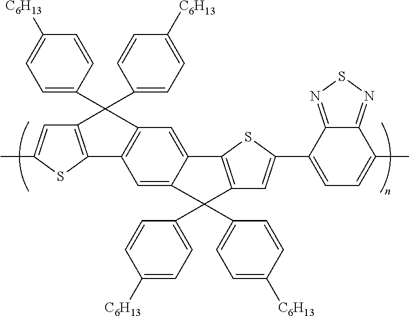

### Example 10

In the example 10 (serving as a comparative example), the first electrode is a Ca/Al electrode, and the first electron transport layer is not configured. Materials of the active layer, the hole transport layer and the second electrode are all the same to that of the embodiment 7.

### Measurement 8: Comparison of Device Performance

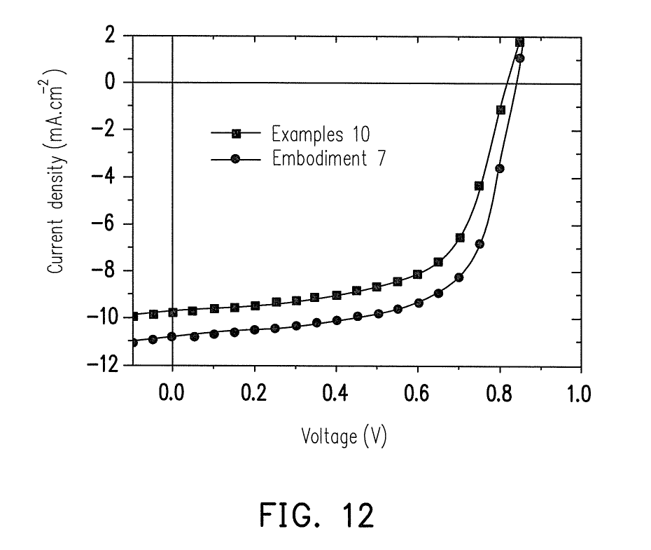

FIG. 12 is a current density and voltage (I-V) diagram of the solar cells of the embodiment 7 and the example 10. Table 9 records data measured in the embodiment 7 and the example 10 and PCEs of the solar cells. According to the following table 9, it is known that the PCE of the solar cell of the embodiment 7 may reach 5.84% maximum and an FF value may reach 64.0%, which is better than that of the example 10.

TABLE 9

| | Voc(V) | Jsc(mA/cm−2) | FF(%) | PCE(%) |
|---|---|---|---|---|
| Example 10 | 0.82 | 9.76 | 61.7 | 4.93 |
| Embodiment 7 | 0.85 | 10.8 | 64.0 | 5.84 |

In summary, in the carrier transport material of the disclosure, the conjugated polyelectrolyte includes the first ionic group, and the functional organic molecule includes the second ionic group, so that electrostatic attraction is formed between the conjugated polyelectrolyte and the functional organic molecule, which promotes functions of carrier transport and interface characteristic improvement. Moreover, the functional organic molecule may further enhance a water resistance of the carrier transport material, so that the electronic device using the above carrier transport material is not liable to be influenced by the moisture in the air and a film-forming property of the carrier transport material is ameliorated. In this way, the electronic device using the above carrier transport material may have good device performance and reliability of device operation is further improved.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A carrier transport material, comprising:
a conjugated polyelectrolyte, comprising a conjugated backbone structure and at least one alkyl side-chain, wherein an end of the alkyl side-chain has a first ionic group; and
a functional organic molecule, comprising a functional main-chain and a second ionic group located at an end of the functional organic molecule,
wherein an electrostatic attraction is formed between the first ionic group of the conjugated polyelectrolyte and the second ionic group of the functional organic molecule, and the carrier transport material presents an electrical neutral state.

2. The carrier transport material as claimed in claim 1, wherein the functional main-chain having the conjugated structure comprises benzene, thiophene, aniline, furan, phenyl vinylene, fluorine or a copolymer of any combination thereof.

3. The carrier transport material as claimed in claim 1, wherein the first ionic group comprises a cationic group containing nitrogen.

4. The carrier transport material as claimed in claim 1, wherein the functional main-chain comprises aromatics with an alkyl chain, aromatics with fluorine-contained groups, aromatics with cross-linkable groups, aliphatics with an alkyl chain, aliphatics with fluorine-contained groups, or aliphatics with cross-linkable groups.

5. The carrier transport material as claimed in claim 1, wherein the second ionic group comprises an anionic group.

6. The carrier transport material as claimed in claim 1, wherein the conjugated polyelectrolyte comprise a structure shown as a formula 1, a formula 2 or a formula 3: 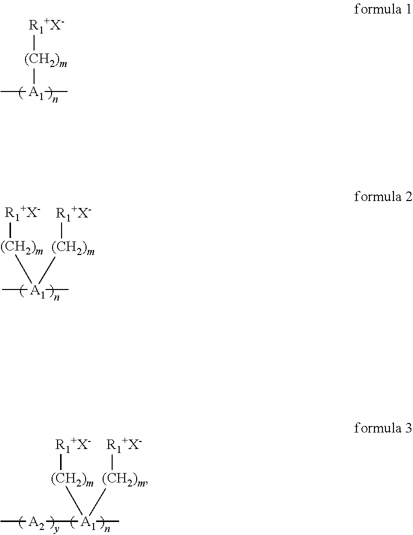
wherein A₁ is a main-chain having conjugated double bonds or conjugated triple bonds, A₂ is a main-chain having conjugated double bonds or conjugated triple bonds, R₁⁺ is a cationic group, X⁻ is an anion, m is 3˜18, n is 2˜1000, and y is 2˜1000;
the functional organic molecule comprises a structure shown as a formula 4:
A₃-R₂⁻M⁺ formula 4
wherein A₂ is an aromatic main-chain or an aliphatic main-chain, R₂⁻ is an anionic group, and M⁺ is a cation.

7. The carrier transport material as claimed in claim 6, wherein R₁⁺ comprises N⁺(CH₃)₃, N⁺(C₂H₅)(CH₃)₂, N⁺(C₂H₅)₂CH₃ or 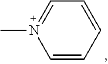
and R₂⁻ comprises SO₃⁻.

8. The carrier transport material as claimed in claim 6, wherein X⁻ is F⁻, Cl⁻, Br⁻ or I⁻, and M⁺ is Li⁺, Na⁺, K⁺ or Rb⁺.

9. The carrier transport material as claimed in claim 1, wherein the conjugated polyelectrolyte comprises at least one of: 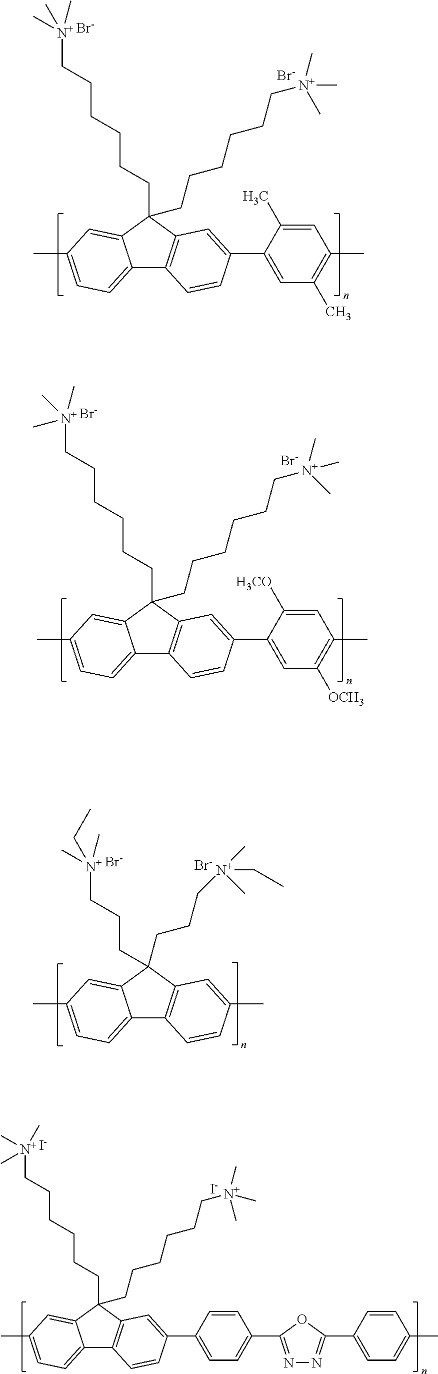 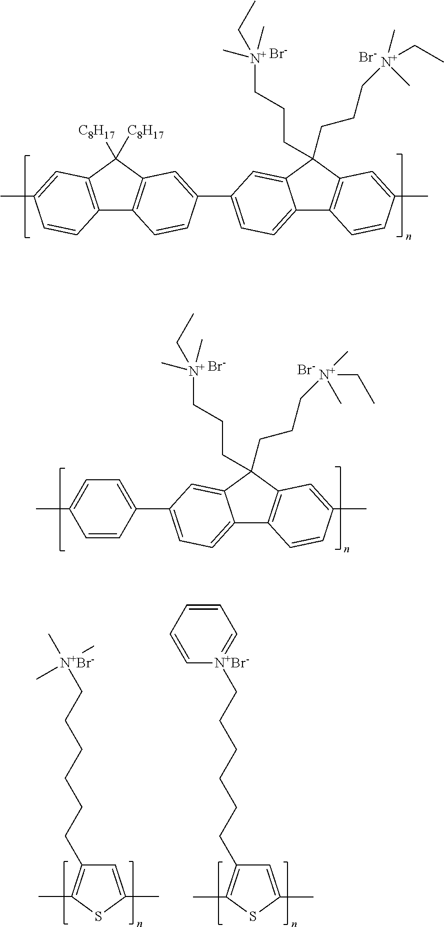 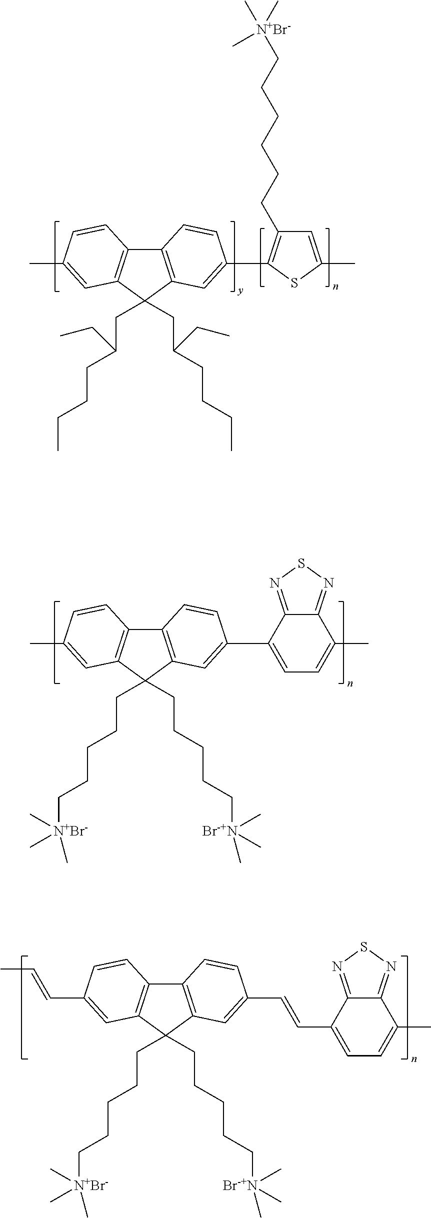 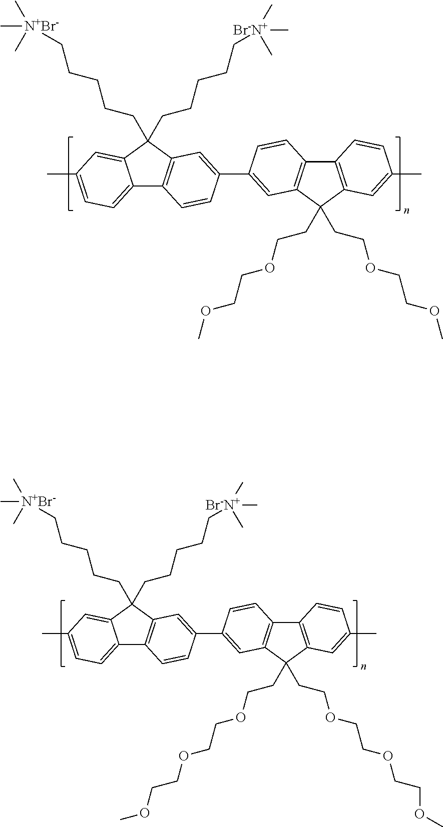
wherein n is 2˜1000, and y is 2˜1000.

10. The carrier transport material as claimed in claim 1, wherein the functional organic molecule comprises at least one of:

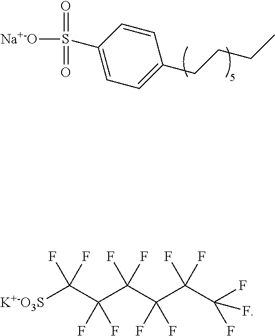

11. An electronic device, comprising
a first electrode and a second electrode, disposed opposite to each other;
an active layer, disposed between the first electrode and the second electrode; and
a first electron transport layer, disposed between the active layer and the first electrode, wherein the first electron transport layer comprises the carrier transport material as claimed in claim 1.

12. The electronic device as claimed in claim 11, further comprising a second electron transport layer disposed between the active layer and the first electrode, wherein the second electron transport layer is disposed between the first electron transport layer and the first electrode, or the second electron transport layer is disposed between the active layer and the first electron transport layer.

13. The electronic device as claimed in claim 12, wherein a material of the second electron transport layer comprises an inorganic oxide.

14. The electronic device as claimed in claim 13, wherein the inorganic oxide comprises zinc oxide, titanium oxide or indium tin oxide.

15. The electronic device as claimed in claim 11, further comprising a hole transport layer disposed between the active layer and the second electrode.

16. The electronic device as claimed in claim 11, wherein the active layer comprises an active layer of a thin-film transistor, an active layer of a solar cell or a light-emitting material layer of an organic light-emitting diode.
